(19) United States
(12) Patent Application Publication
(10) Pub. No.: US 2010/0002019 A1
(43) Pub. Date: Jan. 7, 2010

(54) DIGITAL TO ANALOG CONVERTER, SOURCE DRIVER AND LIQUID CRYSTAL DISPLAY DEVICE INCLUDING THE SAME

(75) Inventors: Woo-Nyoung Lee, Seongnam-si (KR); Chang-Hwe Choi, Yongin-si (KR); Jeung-Tae Park, Yongin-si (KR); Hyung-Tae Kim, Hwaseong-si (KR); Jeong-Ah Ahn, Hwaseong-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 12/394,482

(22) Filed: Feb. 27, 2009

(30) Foreign Application Priority Data
Feb. 29, 2008 (KR) 10-2008-0018957

(51) Int. Cl. G09G 5/10; H03M 1/66

(52) U.S. Cl. 345/690; 341/144; 345/88

(57) ABSTRACT

A digital to analog converter includes a first decoder, a gamma reference voltage decoder unit and an active resistor string unit. The first decoder receives 2^{(N-2)} first gamma voltages and selects 2^{(N-2-P)} second gamma voltages among the first gamma voltages in response to P bit data, where N is an odd number not less than 9, and N−1=2^{P}. The gamma reference voltage decoder unit selects successive two high gamma tab voltages among N high gamma tab voltages in response to the P bit data and provides the selected successive two high gamma tab voltages as a first gamma reference voltage and a second gamma reference voltage. The active resistor string unit divides the first gamma reference voltage and the second gamma reference voltage and provides 2^{(N-2)} grayscale voltages.

### CROSS-REFERENCE TO RELATED APPLICATION

This application claims priority to and the benefit of Korean Patent Application No. 10-2008-0018957, filed on Feb. 29, 2008, in the Korean Intellectual Property Office, the entire content of which is incorporated herein by reference.

### BACKGROUND

1. Field of the Invention

The present invention relates to display devices, and, more particularly, to a liquid crystal display device.

2. Description of the Related Art

A liquid crystal display device is a flat display device that displays an image using a liquid crystal. Typically, in conventional liquid crystal display devices, when the number of digital bits of Red, Green, Blue (RGB) image data is increased so as to enhance color reproduction, the circuit size of a gamma decoder for decoding the RGB image data is significantly increased corresponding to the increase in the number of digital bits.

### SUMMARY

In accordance with exemplary embodiments of the present invention a digital to analog converter is provided capable of enhancing size efficiency and providing a gamma voltage independently per channel.

Exemplary embodiments provide a source driver including the digital to analog converter capable of enhancing size efficiency and providing a gamma voltage independently per channel.

Exemplary embodiments provide a liquid crystal display device including the digital to analog converter capable of enhancing size efficiency and providing a gamma voltage independently per channel.

In an exemplary embodiment a digital to analog converter includes a first decoder, a gamma reference voltage decoder unit and an active resistor string unit. The first decoder receives 2^{(N-2)} first gamma voltages and selects 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of L bit data, successive two low gamma tab voltages being an upper limit and a lower limit of the second gamma voltages, where N is an odd number not less than 9, N−1=2^{P}, and L is a natural number not less than 10. The gamma reference voltage decoder unit selects successive two high gamma tab voltages among N high gamma tab voltages in response to the P bit data and provides the selected successive two high gamma tab voltages as a first gamma reference voltage and a second gamma reference voltage, the N high gamma tab voltages having the uniform voltage difference, the voltage difference between the successive two high gamma tab voltages being equal to the voltage difference between the successive two low gamma tab voltages corresponding to the upper limit and the lower limit of the second gamma voltages. The active resistor string unit divides the first gamma reference voltage and the second gamma reference voltage and provides 2^{(N-2)} grayscale voltages having a uniform voltage difference, the active resistor string unit including multiple transistors having a same gate-source voltage based upon the second gamma voltage.

The digital to analog converter may further include a second decoder, a third decoder and an interpolation buffer. The second decoder may select a first voltage and a second voltage among the 2(N−2) grayscale voltages in response to Q bit data corresponding to intermediate bits of the L bit data, where Q is a natural number less than 10. The third decoder may redundantly select the first voltage and the second voltage and output multiple selected outputs in response to R bit data corresponding least significant bits of the L bit data, where R is a natural number less than 10 and L P+Q+R. The interpolation buffer may average the selected outputs.

The gamma reference voltage decoder unit may include a first gamma reference voltage decoder and a second gamma reference voltage decoder. The first gamma reference voltage decoder may switch the first gamma reference voltage to a first terminal of the active resistor string unit. The second gamma reference voltage decoder may switch the second gamma reference voltage to a second terminal of the active resistor string unit.

The first gamma reference voltage decoder may include multiple first transistors respectively having a source receiving each of odd numbered high gamma tab voltages of the N high gamma tab voltages and the second gamma reference voltage decoder may include multiple second transistors respectively having a drain receiving each of even numbered high gamma tab voltages of the N high gamma tab voltages.

A body of a maximum transistor receiving a maximum voltage of the odd numbered high gamma tab voltages may be connected to a source of the maximum transistor, a body of a minimum transistor receiving a minimum voltage of the odd numbered high gamma tab voltages may be connected to a drain of the minimum transistor, each body of medium transistors receiving respective medium voltage of the odd numbered high gamma tab voltages may be selectively connected to a source or a drain of the respective medium transistors according to the P bit data, where the maximum transistor, the minimum transistor and the medium transistors are included in the first transistors.

Each body of the second transistors may be selectively connected to a source or a drain of the respective second transistors according to the P bit data. The active resistor string unit may include 2^{(N-2-P)}/2 active resistor units connected in series, and the active resistor units may receive the second gamma voltages two by two in voltage order.

Each of the active resistor units may include a first transistor string and a second transistor string connected in series, the first transistor string may include 2^{(N-2-P)}/2 third transistors connected in series and respectively having a gate receiving one of the two second gamma voltages inputted in voltage order, and the second transistor string may include 2^{(N-2-P)}/2 fourth transistors connected in series and respectively having a gate receiving another of the two second gamma voltages inputted in voltage order.

Each body of the third transistors and each body of the fourth transistors may be simultaneously connected to a respective source or a respective drain of the third transistors and the fourth transistors according to the first gamma reference voltage and the second gamma reference voltage.

In an exemplary embodiment a source driver includes a data register unit, a shift register unit, a data latch unit, a digital to analog converter and an output buffer. The data register unit provides a digital data based upon a clock signal and the digital data is L bit data, where L is a natural number not less than 10. The shift register unit receives the clock signal, and outputs a latch control signal that sequentially shifts in response to the received clock signal. The data latch unit sequentially stores the digital data based upon the sequentially-shifting latch control signal. The digital to analog converter receives the digital data from the data latch unit and converts the digital data to an analog data. The output buffer buffers and outputs the converted analog data to a panel in response to a source driver control signal. The digital to analog converter includes a first decoder, a gamma reference voltage decoder unit and an active resistor string unit. The first decoder receives 2^{(N-2)} first gamma voltages and selects 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of L bit data, successive two low gamma tab voltages being an upper limit and a lower limit of the second gamma voltages, where N is an odd number not less than 9, and N−1=2^{P}. The gamma reference voltage decoder unit selects successive two high gamma tab voltages among N high gamma tab voltages in response to the P bit data and provide the selected successive two high gamma tab voltages as a first gamma reference voltage and a second gamma reference voltage, the N high gamma tab voltages having the uniform voltage difference, the voltage difference between the successive two high gamma tab voltages being equal to the voltage difference between the successive two low gamma tab voltages corresponding to the upper limit and the lower limit of the second gamma voltages. The active resistor string unit divides the first gamma reference voltage and the second gamma reference voltage and provides 2^{(N-2)} grayscale voltages having a uniform voltage difference, the active resistor string unit including multiple transistors having a same gate-source voltage based upon the second gamma voltage.

The gamma reference voltage decoder unit may include a first gamma reference voltage decoder and a second gamma reference voltage decoder. The first gamma reference voltage decoder may switch the first gamma reference voltage to a first terminal of the active resistor string unit. The second gamma reference voltage decoder may switch the second gamma reference voltage to a second terminal of the active resistor string unit.

The first gamma reference voltage decoder may include multiple first transistors respectively having a source receiving each of odd numbered high gamma tab voltages of the N high gamma tab voltages and the second gamma reference voltage decoder may include multiple second transistors respectively having a drain receiving each of even numbered high gamma tab voltages of the N high gamma tab voltages.

The active resistor string unit may include 2^{(N-2-P)}/2 active resistor units connected in series, and the active resistor units may receive the second gamma voltages two by two in voltage order.

Each of the active resistor units may include a first transistor string and a second transistor string connected in series, the first transistor string may include 2^{(N-2-P)}/2 third transistors connected in series and respectively having a gate receiving one of the two second gamma voltages inputted in voltage order, and the second transistor string may include 2^{(N-2-P)}/2 fourth transistors connected in series and respectively having a gate receiving another of the two second gamma voltages inputted in voltage order.

Each body of the third transistors and each body of the fourth transistors may be simultaneously connected to a respective source or a respective drain of the third transistors and the fourth transistors according to the first gamma reference voltage and the second gamma reference voltage.

In an exemplary embodiment a liquid crystal display device includes a liquid crystal display panel, a gate driver and a source driver. The liquid crystal display panel includes multiple gate lines and multiple data lines. The gate driver drives the gate lines, and the source driver drives the data lines. The source driver includes a data register unit, a shift register unit, a data latch unit, a digital to analog converter and an output buffer. The data register unit provides a digital data based upon a clock signal. The shift register unit receives the clock signal, and outputs a latch control signal that sequentially shifts in response to the received clock signal. The data latch unit sequentially stores the digital data based upon the sequentially-shifting latch control signal. The digital to analog converter receives the digital data from the data latch unit and converts the digital data to an analog data by using gamma reference voltages that are independent per channel. The output buffer buffers and outputs the converted analog data to a panel in response to a source driver control signal.

The digital data may be L bit data where L is a natural number not less than 10. The digital to analog converter may include a first decoder, a gamma reference voltage decoder unit and an active resistor string unit. The first decoder receives 2^{(N-2)} first gamma voltages and selects 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of the L bit data, successive two low gamma tab voltages being an upper limit and a lower limit of the second gamma voltages, where N is an odd number not less than 9, and N−1=2^{P}. The gamma reference voltage decoder unit selects successive two high gamma tab voltages among N high gamma tab voltages in response to the P bit data and provide the selected successive two high gamma tab voltages as a first gamma reference voltage and a second gamma reference voltage, the N high gamma tab voltages having the uniform voltage difference, the voltage difference between the successive two high gamma tab voltages being equal to the voltage difference between the successive two low gamma tab voltages corresponding to the upper limit and the lower limit of the second gamma voltages. The active resistor string unit divides the first gamma reference voltage and the second gamma reference voltage and provides 2^{(N-2)} grayscale voltages having a uniform voltage difference, the active resistor string unit including multiple transistors having a same gate-source voltage based upon the second gamma voltage.

The gamma reference voltage decoder unit may include a first gamma reference voltage decoder and a second gamma reference voltage decoder. The first gamma reference voltage decoder may switch the first gamma reference voltage to a first terminal of the active resistor string unit. The second gamma reference voltage decoder may switch the second gamma reference voltage to a second terminal of the active resistor string unit.

The first gamma reference voltage decoder may include multiple first transistors respectively having a source receiving each of odd numbered high gamma tab voltages of the N high gamma tab voltages and the second gamma reference voltage decoder may include multiple second transistors respectively having a drain receiving each of even numbered high gamma tab voltages of the N high gamma tab voltages.

The active resistor string unit may include 2^{(N-2-P)}/2 active resistor units connected in series, and the active resistor units may receive the second gamma voltages two by two in voltage order.

Therefore, the digital to analog converter, the source driver and the liquid crystal display device including the digital to analog converter may enhance size efficiency and generate a gamma voltage independent per channel using a transistor string that provides uniform resistance values.

### BRIEF DESCRIPTION OF THE DRAWINGS

FIG. 1 is a block diagram illustrating a liquid crystal display device according to an exemplary embodiment of the present invention.

FIG. 2 is a block diagram illustrating a source driver in the liquid crystal display device of FIG. 1.

FIG. 3 is a block diagram illustrating a digital to analog converter in the source driver of FIG. 2.

FIG. 4A is a block diagram illustrating an active resistor unit in the active resistor string unit of FIG. 3.

FIG. 4B is a block diagram illustrating an active resistor unit in the active resistor string unit of FIG. 4 when the first gamma reference voltage is greater than the second gamma reference voltage.

FIG. 5 is a diagram illustrating a relationship between the high gamma tab voltages and the low gamma tab voltages.

FIG. 6 is a block diagram illustrating a portion of a digital to analog converter according to an exemplary embodiment.

### DETAILED DESCRIPTION OF THE EMBODIMENTS

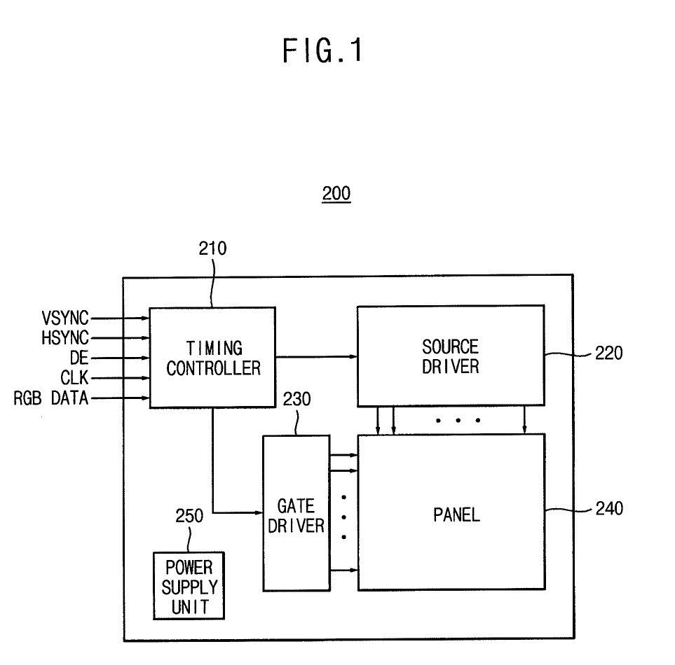

Referring to FIG. 1, a liquid crystal display device 200 includes a timing controller 210, a source driver 220, a gate driver 230, a panel 240 and a power supply unit 250.

The timing controller 210 receives a vertical synchronization signal VSYNC, a horizontal synchronization signal HSYNC, a data enable signal DE, a clock signal CLK and RGB data from a graphic controller (not shown), provides the RGB data and a source driver control signal to the source driver 220 and provides a gate driver control signal to the gate driver 230.

The source driver 220 receives the RGB data and the source driver control signal from the timing controller 210 and outputs the RGB data to the panel 240 in a line unit in response to the horizontal synchronization signal HSYNC.

The gate driver 230 includes multiple gate lines and receives the gate driver control signal from the timing controller 210. The gate driver 230 controls the gate lines so that the panel 240 sequentially displays line by line the RGB data outputted from the source driver 220.

The power supply unit 250 supplies power to the timing controller 210, the source driver 220, the gate driver 230 and the panel 240.

The operation of the liquid crystal display device 200 in FIG. 1 will now be described in more detail.

The timing controller 210 receives the RGB data representing an image to be displayed and also receives control signals such as the vertical synchronization signal VSYNC and the horizontal synchronization signal HSYNC.

The gate driver 230 receives the vertical synchronization signal VSYNC and controls the gate lines such that gate lines are sequentially selected.

The source driver 220 receives the RGB data and the source driver control signal and outputs an image signal corresponding to a gate line as the gate driver 230 sequentially selects the gate line.

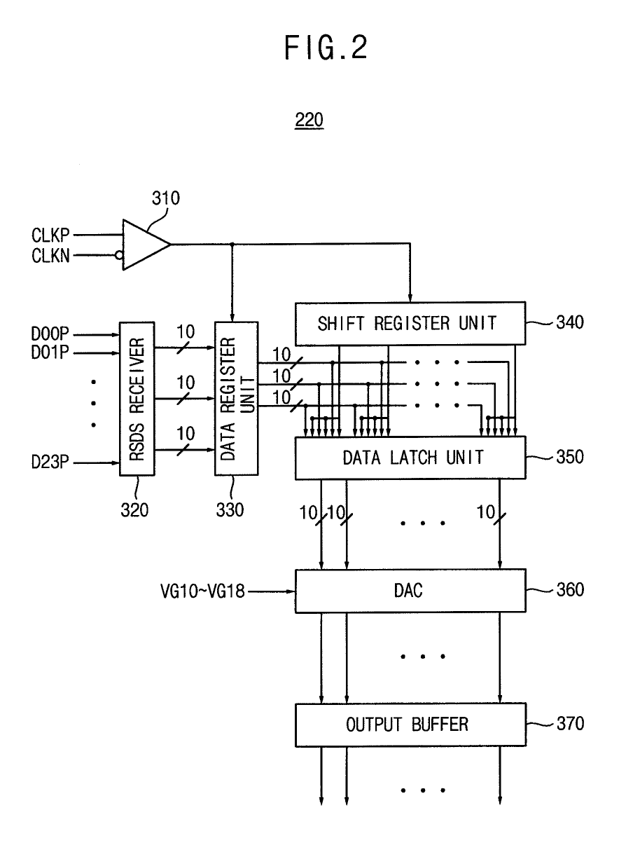

Referring now to FIG. 2, the source driver 220 includes a clock input unit 310, a Reduced Swing Differential Signaling (RSDS) receiver 320, a data register unit 330, a shift register unit 340, a data latch unit 350, a digital to analog converter 360 and an output buffer 370.

The clock input unit 310 receives a clock signal and provides the clock signal to the data register unit 330 and the shift register unit 340. The clock signal is used to synchronize the output of the data register unit 330 and the output of the shift register unit 340.

The RSDS receiver 320 receives a reduced swing differential signal and outputs RGB data to the data register unit 330. For example, each of the RGB data can be 10 bits.

The data register unit 330 outputs the RGB data to the data latch unit 350 in response to the clock signal received from the clock input unit 310. For example, the data register unit 330 can be implemented with registers respectively storing each bit of the RGB data. The data register unit 330 outputs the 10 bit data at the same speed as the operational clock of the RSDS receiver 320.

The shift register unit 340 receives the clock signal from the clock input unit 310 and outputs a latch control signal that sequentially shifts in response to the clock signal. The shift register unit 340 outputs the sequentially-shifting latch control signal to the data latch unit 350.

The data latch unit 350 has multiple latch circuits and the data latch unit 350 receives the sequentially-shifting latch control signal from the shift register unit 340 and RGB data from the data register unit 330. The data latch unit 350 sequentially stores the RGB data in the first through last latch circuits of the data latch unit 350 in response to the sequentially-shifting latch control signal.

The digital to analog converter 360 receives digital data line by line from the data latch unit 350 and converts the digital data to analog data using gamma reference voltages that are channel independent.

The output buffer 370 outputs the analog data converted by the digital to analog converter 360 to the panel 240 in response to the source driver control signal.

The operation of the data register unit 330, the shift register unit 340 and the data latch unit 350 in the source driver 220 will now be described in more detail.

The data register unit 330 and the shift register unit 340 receive the clock signal from the clock input unit 310. The data register unit 330 outputs the RGB data to the data latch unit 350 in response to the received clock signal. The shift register unit 340 performs a shift operation to output the latch control signal to the data latch unit 350, the latch control signal sequentially shifting in response to the clock signal.

The data latch unit 350 sequentially stores the RGB data in the first through last latch circuits constituting the data latch unit 350.

For example, the shift register unit 340 can be implemented with multiple shift registers, with the shift registers being in one-to-one correspondence with the latch circuits constituting the data latch unit 350.

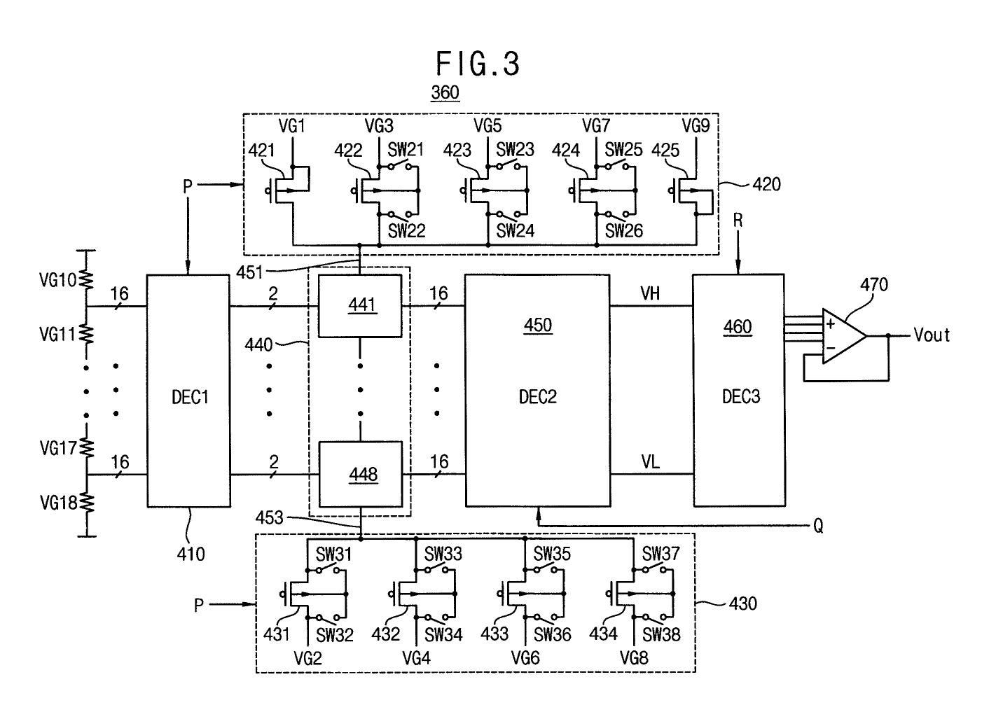

FIG. 3 is a block diagram illustrating a digital to analog converter in the source driver of FIG. 2.

Referring to FIG. 3, a digital to analog converter 360 includes a first decoder 410, a first gamma reference voltage decoder unit 420, a second gamma reference voltage decoder unit 430, an active resistor string unit 440, a second decoder 450, a third decoder 460 and an interpolation buffer 470.

The first decoder 410 receives 2^{(N-2)} first gamma voltages provided by N (N being an odd number not less than 9) low gamma tab voltages respectively having a same voltage difference with one another, for example, the low gamma tab voltages VG10, VG11, . . . VG17, VG18 and 2^{(N-2)} being 128 when N is 9. The first decoder 410 selects second gamma voltages in response to P bit data. Each of successive two low gamma tab voltages (successive two among VG10, . . . VG18) is an upper limit and a lower limit of the second gamma voltages. The P bit data corresponds to significant P bits of L (L=P+Q+R, L being a natural number not less than 10 and P. Q and R being natural numbers less than L) bit data and the P may be 3.

The gamma reference voltage decoder units 420, 430 select successive two high gamma tab voltages from among N high gamma tab voltages VG1, VG2, VG3, VG4, VG5, VG6, VG7, VG8, VG9 in response to the P bit data and provides the selected successive two high gamma tab voltages as a first gamma reference voltage and a second gamma reference voltage. The uniform voltage differences between the high gamma tab voltages VG1, VG2, VG3, VG4, VG5, VG6, VG7, VG8, VG9 is the same as the uniform voltage differences between the low gamma tab voltages VG10, . . . VG18. Thus, the voltage difference between the successive two high gamma tab voltages selected by the gamma reference voltage decoder units 420, 430 is the same as the successive two low gamma tab voltages corresponding the upper limit and the lower limit of the second gamma voltages provided by the first decoder 410. For example, the first gamma reference voltage can be a first high gamma tab voltage VG1 and the second gamma reference voltage can be a second high gamma tab voltage VG2 when the successive two low gamma tab voltages corresponding the upper limit and the lower limit of the second gamma voltages selected by the first decoder 410 are a first low gamma tab voltage VG10 and a second low gamma tab voltage VG11.

The active resistor string unit 440 divides the first gamma reference voltage and the second gamma reference voltage and provides 2^{(N-2)} grayscale voltages having a uniform voltage difference. For example, the first gamma reference voltage can be the first high gamma tab voltage VG1, the second gamma reference voltage can be the second high gamma tab voltage VG2, and the number of grayscale voltages is 128. The active resistor string unit 440 includes multiple transistors that have the same gate-source voltage based upon the second gamma voltage. The active resistor string unit 440 includes active resistor units 441, . . . 448 connected in series between the first and second gamma reference voltage decoder units 420, 430. The number of the active resistor units 441, . . . 448 is half of the number of the second gamma voltages. The active resistor units 441, . . . 448 receive the second gamma voltages two by two in voltage order. That is, the active resistor unit 441 receives the highest two of the second gamma voltages and the active resistor unit 448 receives the lowest two of the second gamma voltages. The active resistor string unit 440 is connected with the first gamma reference voltage decoder 420 through a first terminal 451 and the active resistor string unit 440 is connected with the second gamma reference voltage decoder 430 through a second terminal 453.

The second decoder 450 selects a first voltage VH and a second voltage VL among the 2^{(N-2)} grayscale voltages provided from the active resistor string unit 440 in response to Q bit data and provides the selected first voltage VH and second voltage VL. The Q bit data corresponds to intermediate Q bits of the L bit data, Q being 5. The third decoder 460 redundantly selects the first voltage VH and the second voltage VL in response to R bit data and provides the redundantly selected outputs. The R bit data corresponds to least significant R bits of the L bit data, R being 2. The interpolation buffer 470 averages the selected outputs provided from the third decoder 460 and provides the averaged output as an output voltage Vout.

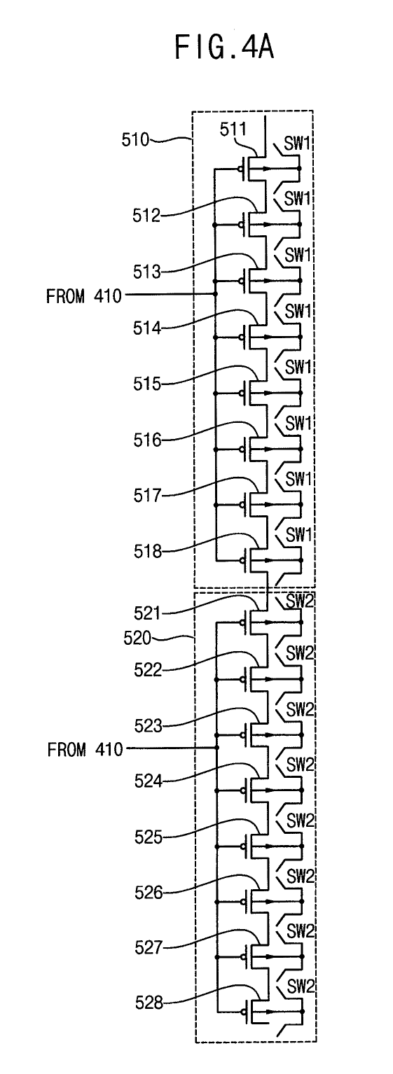

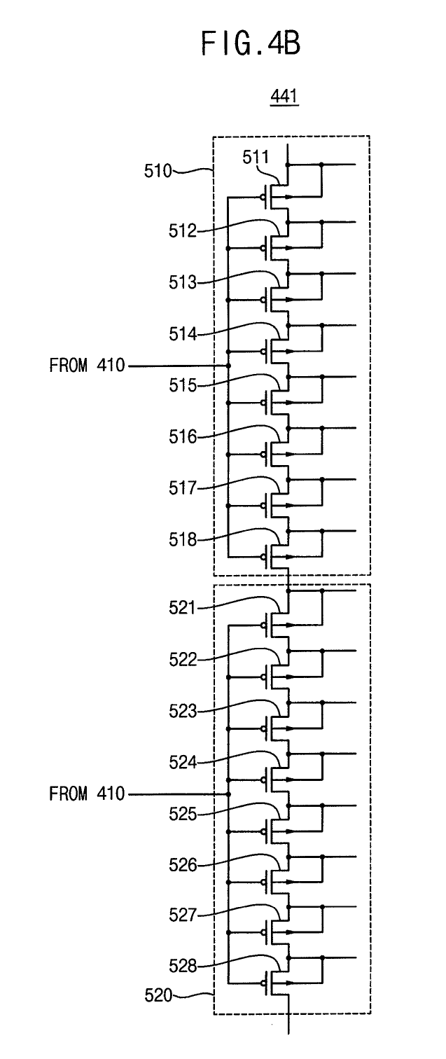

FIG. 4A is a block diagram illustrating an active resistor unit 441 in the active resistor string unit 440 of FIG. 3.

Referring to FIG. 4A, an active resistor unit 441 includes a first transistor string 510 and a second transistor string 520. The first transistor string 510 includes 2^{(N-2-P)}/2 third transistors 511, 512, 513, 514, 515, 516, 517, 518 connected in series and respectively having a gate receiving one of two second gamma voltages that are inputted in voltage order. The first transistor string 510 further includes switches SW1 for simultaneously connecting each body of the third transistors 511, 512, 513, 514, 515, 516, 517, 518 to a respective source or a respective drain thereof according to the first gamma reference voltage and the second gamma reference voltage.

The second transistor string 520 includes 2^{(N-2-P)}/2 fourth transistors 521, 522, 523, 524, 525, 526, 527, 528 connected in series and respectively having a gate receiving another of the two second gamma voltages that are inputted in voltage order. The second transistor string 520 further includes switches SW2 for simultaneously connecting each body of the fourth transistors 521, 522, 523, 524, 525, 526, 527, 528 to a respective source or a respective drain thereof according to the first gamma reference voltage and the second gamma reference voltage. That is, each body of the third transistors 511, 512, 513, 514, 515, 516, 517, 518 and each body of the fourth transistors 521, 522, 523, 524, 525, 526, 527, 528 may be simultaneously connected to the respective source or the respective drain thereof according to the first gamma reference voltage and the second gamma reference voltage.

Structures of other active resistor units 442, . . . 448 are substantially the same as the structure of the active resistor unit 441.

FIG. 4B is a block diagram illustrating an active resistor unit in the active resistor string unit of FIG. 4 when the first gamma reference voltage is greater than the second gamma reference voltage.

FIG. 4B illustrates a block diagram of the active resistor unit 441 when the first gamma reference voltage is selected as the first high gamma tab voltage VG1 by the first gamma reference voltage decoder 420 and the second gamma reference voltage is selected as the second high gamma tab voltage VG2 by the second gamma reference voltage decoder 430. Each body of the third transistors 511, 512, 513, 514, 515, 516, 517, 518 and fourth transistors 521, 522, 523, 524, 525, 526, 527, 528 is connected to the respective source because the first high gamma tab voltage VG1 is greater than the second high gamma tab voltage VG2.

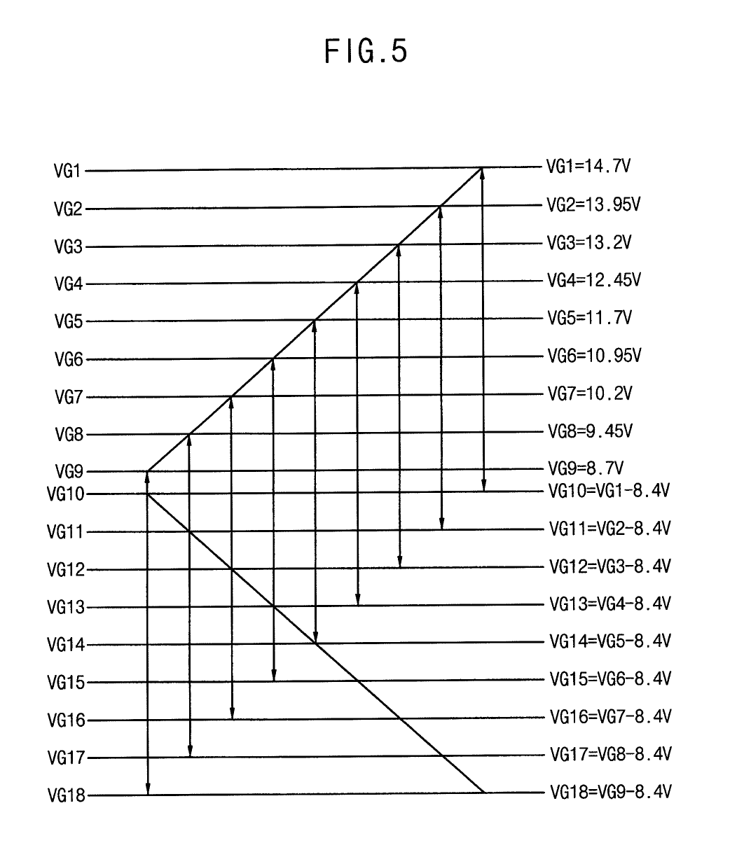

FIG. 5 is a diagram illustrating the relationship between the high gamma tab voltages and the low gamma tab voltages.

Referring to FIG. 5, each of the high gamma tab voltages VG1, VG2, VG3, VG4, VG5, VG6, VG7, VG8, VG9 has a uniform voltage difference (for example, 0.75V). Each of the low gamma tab voltages VG10, VG11, VG12, VG13, VG14, VG15, VG16, VG17, VG18 also has a uniform voltage difference (for example, 0.75V). Therefore, a voltage difference (for example, 8.4V) between each of the high gamma tab voltages VG1, VG2, VG3, VG4, VG5, VG6, VG7, VG8, VG9 and each of the low gamma tab voltages VG10, VG11, VG12, VG13, VG14, VG15, VG16, VG17, VG18 is the same.

The operation of the digital to analog converter will now be described with reference to FIG. 2 through FIG. 5.

The digital to analog converter 360 uses a transistor as a resistor. Each drain-source current (Ids) of the transistors included in the active resistor units 441, . . . 448 constituting the active resistor string unit 440 are the same as each other so that each resistance of the transistors included in the active resistor units 441, . . . 448 is the same as one another.

The drain-source current (Ids) of a normal transistor satisfies Equation 1.

Ids=uₚ*Cₒₓ*W/L*{(Vgs−Vth)*Vds−Vds2/2} [Equation 1]

Here, uₚ denotes mobility of a carrier, Cₒₓ denotes a capacitance of a gate oxide film, W denotes a validity channel width, L denotes a validity channel length, Vgs denotes a gate-source voltage, Vds denotes a drain-source voltage and Vth denotes a threshold voltage.

The uₚ, Cₒₓ, W and L of each transistor in the active resistor units 441, are substantially the same as each other. A body effect may be removed so that each Vth of the transistors are substantially the same as each other. The each body of the third transistors 511, 512, 513, 514, 515, 516, 517, 518 and the fourth transistors 521, 522, 523, 524, 525, 526, 527, 528 is connected to the respective source so as to remove the body effect. The high gamma tab voltages VG1, VG2, VG3, VG4, VG5, VG6, VG7, VG8, VG9 have a uniform voltage difference and the low gamma tab voltages VG10, VG11, . . . VG17, VG18 have a uniform voltage difference so as to equalize Vds of the transistors in the active resistor units 441, . . . 448.

A fixed voltage lower than a voltage applied to the respective source of the third transistors 511, 512, 513, 514, 515, 516, 517, 518 and the fourth transistors 521, 522, 523, 524, 525, 526, 527, 528 may be applied to a respective gate of the third transistors 511, 512, 513, 514, 515, 516, 517, 518 and the fourth transistors 521, 522, 523, 524, 525, 526, 527, 528 so as to equalize Vgs of the transistors in the active resistor units 441, . . . 448.

For example, when the first gamma reference voltage decoder unit 420 selects the first high gamma tab voltage VG1 and the second gamma reference voltage decoder unit 430 selects the second high gamma tab voltage VG2, the first decoder 410 selects the sixteen second gamma voltages corresponding to the first low gamma tab voltage VG10 and the second low gamma tab voltage VG11 and provides the selected second gamma voltages to the eight active resistor units 441, . . . 448 two by two in order. Therefore, each resistance of the transistors in the active resistor string unit 440 is the same as one another.

The first gamma reference voltage decoder 420 and the second gamma reference voltage decoder 430 receive the P bit (3-bit) data at the same time as the first decoder 410. The first gamma reference voltage decoder 420 includes first transistors 421, 422, 423, 424, 425 and the second gamma reference voltage decoder 430 includes second transistors 431, 432, 433, 434. Each source of the first transistors 421, 422, 423, 424, 425 receives respective odd numbered high gamma tab voltages VG1, VG3, VG5, VG7, VG9 of the N high gamma tab voltages VG1, VG2, VG3, VG4, VG5, VG6, VG7, VG8, VG9. Each source of the second transistors 431, 432, 433, 434 receives respective even numbered high gamma tab voltages VG2, VG4, VG6, VG8 of the N high gamma tab voltages VG1, VG2, VG3, VG4, VG5, VG6, VG7, VG8, VG9.

The first high gamma tab voltage VG1 is a maximum voltage of the odd numbered high gamma tab voltages VG1, VG3, VG5, VG7, VG9, The ninth high gamma tab voltage VG9 is a minimum voltage of the odd numbered high gamma tab voltages VG1, VG3, VG5, VG7, VG9 and the third, fifth and seventh high gamma tab voltages VG3, VG5, VG7 are medium voltages of the odd numbered high gamma tab voltages VG1, VG3, VG5, VG7, VG9.

A body of the first transistor 421 receiving the maximum voltage VG1 is connected to a source of the first transistor 421. A body of the first transistor 425 receiving the minimum voltage VG9 is connected to a drain of the first transistor 425. Each body of the first transistors 422, 423, 424 receiving respective medium voltages VG3, VG5, VG7 is selectively connected to a respective source or a respective drain thereof by switches SW21, SW22, SW23, SW24, SW25, SW26 according to the P bit data.

Each body of the second transistors 431, 432, 433, 434 is selectively connected to a respective source of a respective drain thereof by switches SW31, SW32, SW33, SW34, SW35, SW36, SW37, SW38 according to the P bit data.

For example, when the first gamma reference voltage decoder 420 selects the first high gamma tab voltage VG1 and the second gamma reference voltage decoder 430 selects the second high gamma tab voltage VG2 according to the P bit data, the body of the second transistor 431 is connected to the drain of the second transistor 431 by the switch SW32. When the first gamma reference voltage decoder 420 selects the third high gamma tab voltage VG3 and the second gamma reference voltage decoder 430 selects the second high gamma tab voltage VG2 according to the P bit data, the body of the second transistor 431 is connected to the source of the second transistor 431 by the switch SW31 and the body of the first transistor 422 is connected to the drain by the switch SW22.

The first gamma reference voltage and the second gamma reference voltage is changed according to the P bit data and the each body of the first and second transistors 421, 422, 423, 424, 425, 431, 432, 433, 434 is selectively connected to the respective source or the respective drain thereof. Therefore, an avalanche break down due to a reverse bias voltage may be prevented.

Table 1 illustrates the relationships between the high gamma tab voltages VG1, VG2, VG3, VG4, VG5, VG6, VG7, VG8, VG9, the low gamma tab voltages VG10, VG11, . . . VG17, VG18 and switches SW21, SW22, SW23, SW24, SW25, SW26, SW31, SW32, SW33, SW34, SW35, SW36, SW37, SW38 according to the P bit data.

TABLE 1

| | high gamma tab | low gamma tab | connection of |
|---|---|---|---|
| P bit data | voltages | voltages | switch |
| 000 | VG1~VG2 | VG10~VG11 | SW32 |
| 001 | VG2~VG3 | VG11~VG12 | SW31, SW22 |
| 010 | VG3~VG4 | VG12~VG13 | SW21, SW34 |
| 011 | VG4~VG5 | VG13~VG14 | SW33, SW24 |
| 100 | VG5~VG6 | VG14~VG15 | SW23, SW36 |
| 101 | VG6~VG7 | VG15~VG16 | SW35, SW26 |
| 110 | VG7~VG8 | VG16~VG17 | SW25, SW38 |
| 111 | VG8~VG9 | VG17~VG18 | SW37 |

The second decoder 450 selects the first voltage VH and the second voltage VL among the 128 grayscale voltages provided from the active resistor string unit 440 in response to the Q bit data (for example, 5 bit data) and provides the selected first voltage VH and second voltage VL to the third decoder 460.

The third decoder 460 redundantly selects the first voltage VH and the second voltage VL in response to the R bit data (for example, two bit data) and outputs the redundantly selected output voltages. The output voltages of the third decoder 460 are one of (VH, VH, VH, VH), (VH, VH, VH, VL), (VH, VH, VL, VL) or (VH, VL, VL, VL) when the R bit data is two bit data.

The interpolation buffer 470 averages the output voltages of the third decoder 460 and outputs the averaged output as the output voltage Vout. The output voltage Vout is one of VH, (3VH+VL)/4, (VH+VL)/2 and (VH+3VL)/4.

The digital to analog converter 360 generates 1024 grayscale voltages from 128 grayscale voltages input to the first decoder 410 by implementing 3 bits in the first decoder 410, and the gamma reference voltage decoders 420, 430, by implementing 5 bits in the second decoder 450, and by implementing 2 bits in the third decoder 460.

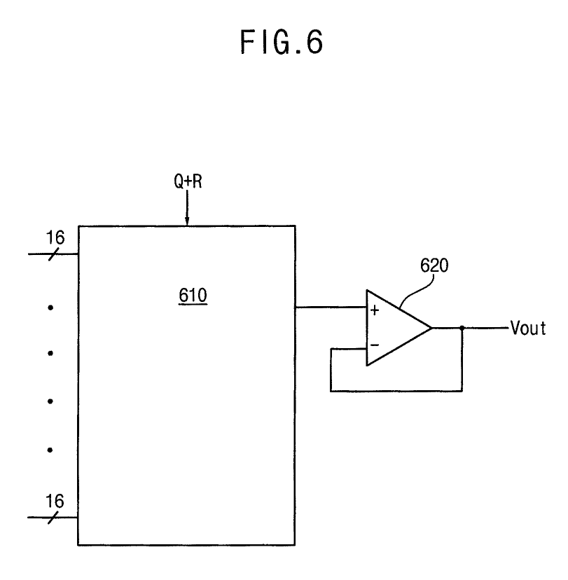

The structures of the second decoder 450, the third decoder 460 and the interpolation buffer 470 may be changed as shown in FIG. 6 which is a block diagram illustrating a portion of a digital to analog converter according to an exemplary embodiment of the present invention.

Referring to FIG. 6, the second decoder 450 and the third decoder 460 in FIG. 2 are replaced with a second decoder 610 and the interpolation buffer 470 in FIG. 2 is replaced with a buffer 620.

The second decoder 610 selects a grayscale voltage of the 128 grayscale voltages provided from the active resistor string unit 440 in response to (Q+R) bit data and provides the selected grayscale voltage to the buffer 620. For example, (Q+R) is 7. The buffer 620 buffers the grayscale voltage provided from the second decoder 610 and outputs the buffered grayscale voltage as an output voltage Vout.

Referring again to FIGS. 1 through 5, the digital to analog converter 360 according to the exemplary embodiments of the present invention generates a gamma voltage that is independent per channel by selecting the high gamma tab voltages VG1, VG2, VG3, VG4, VG5, VG6, VG7, VG8, VG9 and the low gamma tab voltages VG10, . . . VG18 independently according to the channel. Also, the digital to analog converter 360 is implementable in a small size as compared with a conventional resistor string type digital to analog converter.

Therefore, the digital to analog converter 360 according to at least one exemplary embodiment of the present invention can enhance size efficiency and generate an independent gamma voltage according to a channel by using a transistor string having the same resistances. As such, the digital to analog converter 360 can be applied to a display device requiring a high resolution, a high color resolution and a high speed operation.

While exemplary embodiments of the present invention have been described in detail, it should be understood that various changes, substitutions and alterations may be made herein without departing from the scope of the invention.

What is claimed is:

1. A digital to analog converter comprising:
a first decoder configured to receive 2^{(N-2)} first gamma voltages and select 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of L bit data, successive two low gamma tab voltages being an upper limit and a lower limit of the second gamma voltages, N being an odd number not less than 9, N−1 being equal to 2^{P}, L being a natural number not less than 10;
a gamma reference voltage decoder unit configured to select successive two high gamma tab voltages among N high gamma tab voltages in response to the P bit data and provide selected successive two high gamma tab voltages as a first gamma reference voltage and a second gamma reference voltage, the N high gamma tab voltages having the uniform voltage difference, a voltage difference between the successive two high gamma tab voltages being equal to a voltage difference between the successive two low gamma tab voltages corresponding to the upper limit and the lower limit of the second gamma voltages; and
an active resistor string unit configured to divide the first gamma reference voltage and the second gamma reference voltage and provide 2^{(N-2)} grayscale voltages having a uniform voltage difference, the active resistor string unit including a plurality of transistors having a same gate-source voltage based on the second gamma voltage.

2. The digital to analog converter of claim 1, further comprising:
a second decoder configured to select a first voltage and a second voltage among the 2^{(N-2)} grayscale voltages in response to Q bit data corresponding to intermediate bits of the L bit data, Q being a natural number less than 10;
a third decoder configured to redundantly select the first voltage and the second voltage and output a plurality of selected outputs in response to R bit data corresponding least significant bits of the L bit data, R being a natural number less than 10, L being equal to P+Q+R; and
an interpolation buffer configured to average the selected outputs.

3. The digital to analog converter of claim 1, wherein the gamma reference voltage decoder unit includes:
a first gamma reference voltage decoder configured to switch the first gamma reference voltage to a first terminal of the active resistor string unit; and
a second gamma reference voltage decoder configured to switch the second gamma reference voltage to a second terminal of the active resistor string unit.

4. The digital to analog converter of claim 3, wherein:
the first gamma reference voltage decoder includes a plurality of first transistors respectively having a source receiving each of odd numbered high gamma tab voltages of the N high gamma tab voltages, and
the second gamma reference voltage decoder includes a plurality of second transistors respectively having a drain receiving each of even numbered high gamma tab voltages of the N high gamma tab voltages.

5. The digital to analog converter of claim 4, wherein:
a body of a maximum transistor receiving a maximum voltage of the odd numbered high gamma tab voltages is connected to a source of the maximum transistor,
a body of a minimum transistor receiving a minimum voltage of the odd numbered high gamma tab voltages is connected to a drain of the minimum transistor,
each body of medium transistors receiving respective medium voltage of the odd numbered high gamma tab voltages is selectively connected to a source or a drain of the respective medium transistors according to the P bit data, and
the maximum transistor, the minimum transistor and the medium transistors are included in the first transistors.

6. The digital to analog converter of claim 5, wherein each body of the second transistors is selectively connected to a source or a drain of the respective second transistors according to the P bit data.

7. The digital to analog converter of claim 3, wherein the active resistor string unit includes 2^{(N-2-P)}/2 active resistor units connected in series, the active resistor units receiving the second gamma voltages two by two in voltage order.

8. The digital to analog converter of claim 7, wherein each of the active resistor units includes a first transistor string and a second transistor string connected in series, the first transistor string including 2^{(N-2-P)}/2 third transistors connected in series and respectively having a gate receiving one of the two second gamma voltages inputted in voltage order, the second transistor string including 2^{(N-2-P)}/2 fourth transistors connected in series and respectively having a gate receiving another of the two second gamma voltages inputted in voltage order.

9. The digital to analog converter of claim 8, wherein each body of the third transistors and each body of the fourth transistors are simultaneously connected to a respective source or a respective drain of the third transistors and the fourth transistors according to the first gamma reference voltage and the second gamma reference voltage.

10. A source driver comprising:
a data register unit configured to provide a digital data based on a clock signal, the digital data being L bit data, L being a natural number not less than 10;
a shift register unit configured to receive the clock signal and to output a latch control signal that sequentially shifts in response to the received clock signal;
a data latch unit configured to sequentially store digital data based on a sequentially-shifting latch control signal;
a digital to analog converter configured to receive the digital data from the data latch unit and convert the digital data to analog data; and
an output buffer configured to buffer and output converted analog data to a panel in response to a source driver control signal,
the digital to analog converter comprising:
a first decoder configured to receive 2^{(N-2)} first gamma voltages and select 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of the L bit data, successive two low gamma tab voltages being an upper limit and a lower limit of the second gamma voltages, N being an odd number not less than 9, N−1=2^{P};
a gamma reference voltage decoder unit configured to select successive two high gamma tab voltages among N high gamma tab voltages in response to the P bit data and provide selected successive two high gamma tab voltages as a first gamma reference voltage and a second gamma reference voltage, the N high gamma tab voltages having the uniform voltage difference, a voltage difference between the successive two high gamma tab voltages being equal to a voltage difference between the successive two low gamma tab voltages corresponding to the upper limit and the lower limit of the second gamma voltages; and
an active resistor string unit configured to divide the first gamma reference voltage and the second gamma reference voltage and provide 2^{(N-2)} grayscale voltages having a uniform voltage difference, the active resistor string unit including a plurality of transistors having a same gate-source voltage based on the second gamma voltage.

11. The source driver of claim 10, wherein the gamma reference voltage decoder unit includes:
a first gamma reference voltage decoder configured to switch the first gamma reference voltage to a first terminal of the active resistor string unit; and
a second gamma reference voltage decoder configured to switch the second gamma reference voltage to a second terminal of the active resistor string unit.

12. The source driver of claim 11, wherein:
the first gamma reference voltage decoder includes a plurality of first transistors respectively having a source receiving each of odd numbered high gamma tab voltages of the N high gamma tab voltages, and
the second gamma reference voltage decoder includes a plurality of second transistors respectively having a drain receiving each of even numbered high gamma tab voltages of the N high gamma tab voltages.

13. The source driver of claim 10, wherein the active resistor string unit includes 2^{(N-2-P)}/2 active resistor units connected in series, the active resistor units receiving the second gamma voltages two by two in voltage order.

14. The source driver of claim 13, wherein each of the active resistor units includes a first transistor string and a second transistor string connected in series, the first transistor string including 2^{(N-2-P)}/2 third transistors connected in series and respectively having a gate receiving one of the two second gamma voltages inputted in voltage order, the second transistor string including 2^{(N-2-P)}/2 fourth transistors connected in series and respectively having a gate receiving another of the two second gamma voltages inputted in voltage order.

15. The source driver of claim 14, wherein each body of the third transistors and each body of the fourth transistors are simultaneously connected to a respective source or a respective drain of the third transistors and the fourth transistors according to the first gamma reference voltage and the second gamma reference voltage.

16. A liquid crystal display device comprising:
a liquid crystal display panel including a plurality of gate lines and a plurality of data lines;
a gate driver configured to drive the gate lines; and
a source driver configured to drive the data lines,
the source driver comprising:
a data register unit configured to provide digital data based on a clock signal;
a shift register unit configured to receive the clock signal and to output a latch control signal that sequentially shifts in response to a received clock signal;
a data latch unit configured to sequentially store digital data based on a sequentially-shifting latch control signal;
a digital to analog converter configured to receive the digital data from the data latch unit and convert the digital data to analog data using gamma reference voltages that are independent per channel; and
an output buffer configured to buffer and output converted analog data to the liquid crystal display panel in response to a source driver control signal.

17. The liquid crystal display device of claim 16, wherein:
the digital data is L bit data, L being a natural number not less than 10, and
the digital to analog converter includes:
a first decoder configured to receive 2^{(N-2)} first gamma voltages and select 2^{(N-2-P)} second gamma voltages among the 2^{(N-2)} first gamma voltages in response to P bit data, the first gamma voltages provided by N low gamma tab voltages having a uniform voltage difference, the P bit data corresponding to significant bits of the L bit data, successive two low gamma tab voltages being an upper limit and a lower limit of the second gamma voltages, N being an odd number not less than 9, N−1 being equal to 2^{P};
a gamma reference voltage decoder unit configured to select successive two high gamma tab voltages among N high gamma tab voltages in response to the P bit data and provide selected successive two high gamma tab voltages as a first gamma reference voltage and a second gamma reference voltage, the N high gamma tab voltages having the uniform voltage difference, a voltage difference between the successive two high gamma tab voltages being equal to a voltage difference between the successive two low gamma tab voltages corresponding to the upper limit and the lower limit of the second gamma voltages; and
an active resistor string unit configured to divide the first gamma reference voltage and the second gamma reference voltage and provide 2^{(N-2)} grayscale voltages having a uniform voltage difference, the active resistor string unit including a plurality of transistors having a same gate-source voltage based on the second gamma voltage.

18. The liquid crystal display device of claim 17, wherein the gamma reference voltage decoder unit includes:
a first gamma reference voltage decoder configured to switch the first gamma reference voltage to a first terminal of the active resistor string unit; and
a second gamma reference voltage decoder configured to switch the second gamma reference voltage to a second terminal of the active resistor string unit.

19. The liquid crystal display device of claim 18, wherein:
the first gamma reference voltage decoder includes a plurality of first transistors respectively having a source receiving each of odd numbered high gamma tab voltages of the N high gamma tab voltages, and
the second gamma reference voltage decoder includes a plurality of second transistors respectively having a drain receiving each of even numbered high gamma tab voltages of the N high gamma tab voltages.

20. The liquid crystal display device of claim 17, wherein the active resistor string unit includes 2^{(N-2-P)}/2 active resistor units connected in series, the active resistor units receiving the second gamma voltages two by two in voltage order.
